(19) United States
(12) Patent Application Publication
(10) Pub. No.: US 2019/0081456 A1
(43) Pub. Date: Mar. 14, 2019

(54) SEMICONDUCTOR LASER DEVICE

(71) Applicant: KABUSHIKI KAISHA TOSHIBA, Minato-ku (JP)

(72) Inventors: Osamu YAMANE, Yokohama (JP); Shinji SAITO, Yokohama (JP); Tsutomu KAKUNO, Fujisawa (JP); Kei KANEKO, Yokohama (JP); Rei HASHIMOTO, Edogawa (JP)

(73) Assignee: KABUSHIKI KAISHA TOSHIBA, Minato-ku (JP)

(21) Appl. No.: 16/084,490

(22) PCT Filed: Sep. 2, 2016
(86) PCT No.: PCT/JP2016/075859

§ 371 Date: Sep. 12, 2018

(30) Foreign Application Priority Data
Mar. 15, 2016 (JP) 2016-051671

(51) Int. Cl. H01S 5/12; H01S 5/18; H01S 5/34; H01S 5/042

(52) U.S. Cl. CPC H01S 5/12; H01S 5/0425; H01S 5/3402; H01S 5/18

(57) ABSTRACT

A semiconductor laser device includes an active layer, a first layer, and a surface metal film. Multiple quantum well layers are stacked in the active layer; and the active layer is configured to emit laser light of a terahertz wave by an intersubband transition. The first layer is provided on the active layer and includes a first surface in which multiple pits are provided to form a two-dimensional lattice. The surface metal film is provided on the first layer and includes multiple openings. Each of the pits is asymmetric with respect to a line parallel to a side of the lattice. The laser light passes through the multiple openings and is emitted in a direction substantially perpendicular to the active layer.

### TECHNICAL FIELD

This invention relates to a semiconductor laser device.

### BACKGROUND ART

When using a quantum cascade laser as a light source of a terahertz wave, a laser oscillation of 30 GHz to 30 THz is possible due to an intersubband transition of electrons.

In the case where an edge emitting quantum cascade laser is used as the light source, a collimator lens is necessary to cause the spreading laser light emitted from the end surface to be parallel light; and the exterior form of the laser device becomes large.

### PRIOR ART DOCUMENT

### Patent Document

[Patent Document 1] JP 2009-231773 (Kokai)

### SUMMARY OF INVENTION

### Problem to be Solved by the Invention

A semiconductor laser device is provided that is capable of emitting a terahertz wave of a plane wave with high efficiency.

### Means for Solving the Problem

A semiconductor laser device of an embodiment includes an active layer, a first layer, and a surface metal film. Multiple quantum well layers are stacked in the active layer; and the active layer is configured to emit laser light of a terahertz wave by an intersubband transition. The first layer is provided on the active layer and has a first surface in which multiple pits are provided to form a two-dimensional lattice. The surface metal film is provided on the first layer and has multiple openings. Each of the pits is asymmetric with respect to a line parallel to a side of the lattice. The laser light passes through the multiple openings and is emitted in a direction substantially perpendicular to the active layer.

### BRIEF DESCRIPTION OF DRAWINGS

FIG. 1 is a schematic perspective view of a semiconductor laser device according to a first embodiment.

FIG. 2 is a schematic plan view of the surface metal film of the semiconductor laser device according to the first embodiment.

FIG. 3 is a graph illustrating the transmittance for the frequency of the terahertz wave of the surface metal film of the semiconductor laser device according to the first embodiment.

FIG. 4 is a schematic plan view illustrating a modification of the surface metal film.

FIG. 5 is a schematic plan view illustrating another example of the arrangement of the openings of the surface metal film.

FIG. 6 is a schematic plan view of the surface emitting portion of the semiconductor laser device of the first embodiment.

FIG. 7 is a schematic plan view of the first electrode of the surface emitting portion.

FIG. 8 is a partial schematic perspective view of the pit portion.

FIG. 9 is a graph illustrating the current injection uniformity dependence and the relative light extraction efficiency dependence with respect to the number of pits.

FIG. 10 is a schematic perspective view of a semiconductor laser device according to a second embodiment.

FIG. 11 is a configuration diagram of a laser device according to a comparative example.

### EMBODIMENT OF INVENTION

Embodiments of the invention will now be described with reference to the drawings.

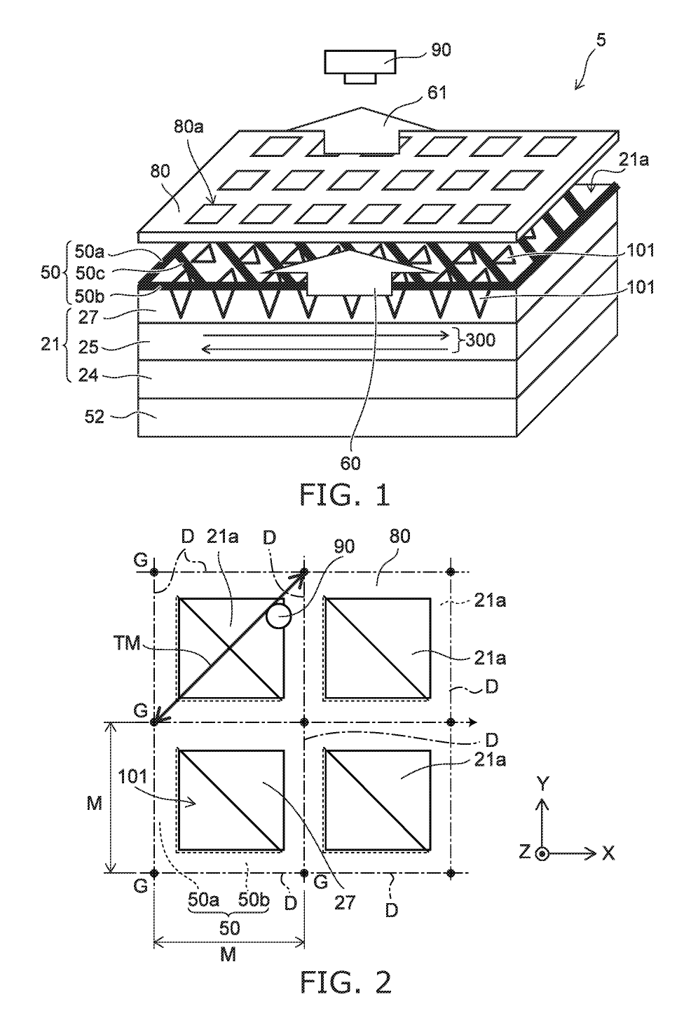

FIG. 1 is a schematic perspective view of a semiconductor laser device according to a first embodiment.

The semiconductor laser device 5 includes an active layer 25, a first layer 27, and a surface metal film 80. Multiple quantum well layers are stacked in the active layer 25; and the active layer 25 is configured to emit laser light of a terahertz wave by an intersubband transition. In the specification, the terahertz wave is taken to be not less than 30 GHz and not more than 30 THz.

The first layer 27 is provided on the active layer 25 and has a first surface 21a in which multiple pits 101 are provided to form a two-dimensional lattice. The surface metal film 80 is provided on the first layer 27; and multiple openings 80a are provided in the surface metal film 80. The openings 80a can be, for example, the gaps of a metal mesh, etc.

The planar configuration of each of the pits 101 is asymmetric with respect to a line parallel to a side of the lattice. Also, laser light 60 passes through the multiple openings 80a and is emitted in a direction substantially perpendicular to the front surface of the active layer 25. The light intensity of laser light 61 emitted by passing through the openings 80a of the surface metal film 80 is measured by a detector 90 such as a bolometer, etc. In the specification, the substantially perpendicular direction is not less than 81 degrees and not more than 99 degrees with respect to the front surface of the active layer 25.

In the embodiment, the semiconductor laser device 5 further includes a first electrode 50 provided between the first layer 27 and the surface metal film 80, electrically connected to the surface of the first layer 27, but insulated from the surface metal film 80. Although the surface metal film 80 is illustrated as being separated from the surfaces of the first layer 27 and the first electrode 50 in FIG. 1, actually, the surface metal film 80 is stacked with an insulating body or the like interposed.

A stacked body 21 includes the first layer 27, the active layer 25, and a second layer. The multiple pits 101 that have opening ends at the first surface 21a of the stacked body 21 are provided in a two-dimensional lattice configuration and act as a periodic-structure PC (photonic crystal). For example, the pits 101 have configurations in which triangular pyramid regions are cut out from the first surface 21a of the stacked body 21 toward the depth direction.

The laser light 60 can have optical resonance along a QCL optical resonance direction 300 inside the active layer 25; and the mode is selected by the periodic-structure PC and further emitted from the first surface 21a along an optical axis substantially perpendicular to the first surface 21a due to a diffraction effect. In other words, the region lower than the first electrode 50 functions as a surface emitting portion. A voltage is supplied above and below the stacked body 21.

FIG. 2 is a schematic plan view of the surface metal film of the semiconductor laser device according to the first embodiment.

In the drawing, one opening 80a of the surface metal film 80 is provided for four pits 101. The laser light 60 is emitted from the surface emitting portion in an upward direction substantially perpendicular to the front surface of the active layer 25, passes through the openings 80a, and is emitted to the outside. The laser light 60 is a TM (Transverse Magnetic) wave polarized in the direction of the arrow.

For the square lattice that forms the periodic-structure PC, the crossing point of two orthogonal sides D and E in the XY plane is taken as a lattice point G; and the lattice spacing of the square lattice is taken as M. For example, the lattice point G can be considered to be the centroid of the planar configuration of the pit 101, etc. Each of the pits 101 has non-line symmetry with respect to one side of the two sides D or E of the square lattice. The lattice may not be a square lattice and may be a lattice in which two sides are orthogonal.

A portion of the terahertz wave can pass through the opening 80a. For example, by changing the configuration and/or the size of the opening 80a, the transmittance of a tera hertz wave of a wavelength of the width of the opening 80a or more can be set to 50% or more. Also, the surface metal film 80 in which the openings 80a are provided acts as an external (LC) resonator for the terahertz wave. In the case where a fine particle 90 including a dielectric adheres at the opening 80a vicinity of the surface metal film 80, the resonant frequency of the external resonator changes. Therefore, the peak frequency of the transmission spectrum shifts. In other words, the first embodiment can emit a plane wave terahertz wave with high efficiency by using a metamaterial as the surface metal film 80.

Also, in the semiconductor laser device 5 of the first embodiment, the transmission peak frequency can be shifted because the surface metal film 80 is used as an external resonator. The detection of fine particles, etc., can be performed by detecting the shift of the transmission peak frequency. For example, it is taken that the fine particle 90 including a microbe, bacteria such as coliform bacteria, or the like is adhered at the opening 80a vicinity of the surface metal film 80 of the opening 80a.

In the case where the wavelength of the laser light is near visible light, the change of the transmittance due to the fine particles 90 is reduced by the amount of a region corresponding to the cross-sectional area of the fine particles 90 and is therefore small. Conversely, in the case where the wavelength of the laser light is near a terahertz wave, the shift amount of the resonant frequency is large even if the amount of the fine particles 90 is low; therefore, the change of the transmittance is in a wide frequency range. Therefore, the existence or absence of the fine particles 90 can be detected with high accuracy. The fine particles 90 include PM 2.5, etc.

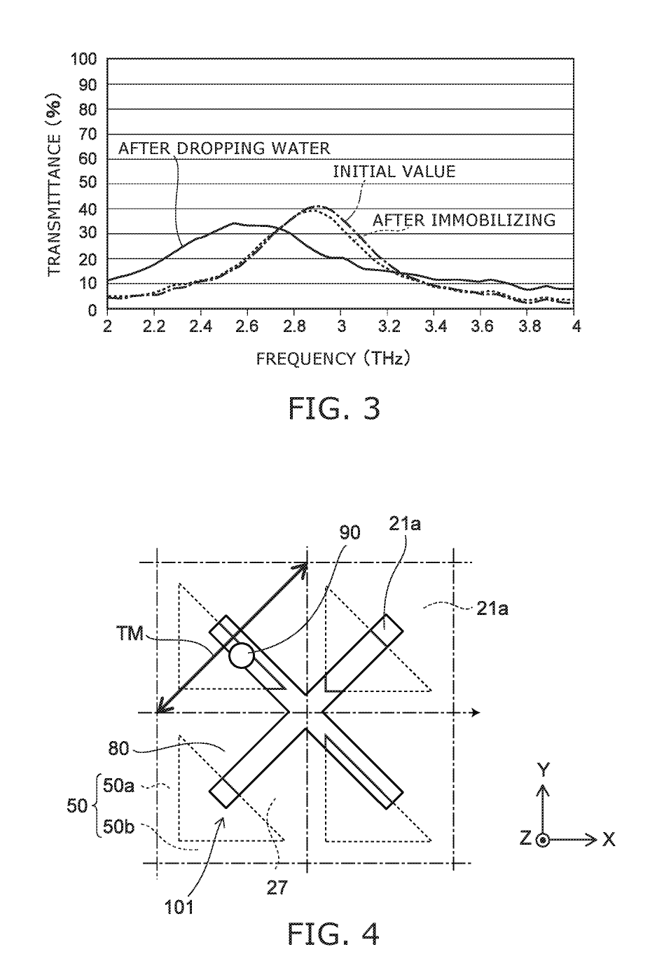

FIG. 3 is a graph illustrating the transmittance for the frequency of the terahertz wave of the surface metal film of the semiconductor laser device according to the first embodiment.

The vertical axis is the transmittance (%); and the horizontal axis is the frequency (THz) of the terahertz wave. After immobilizing coliform bacteria, water was dropped; and the transmission spectrum was measured. The initial state is illustrated by the broken line; the state after the coliform bacteria immobilization is illustrated by the dotted line; and the state after the dropping of the water is illustrated by the solid line. The transmission spectrum intensity is measurable using a spectrometer, etc.

By immobilizing the coliform bacteria, the peak frequency decreased about 25 GHz with respect to the initial state. By dropping the water, the peak frequency decreased about 300 GHz (the transmittance was about 33%). The absorption coefficient of water for the terahertz wave is high and is about 10⁶ times the absorption coefficient for visible light or the like. Therefore, the shift amount of the resonant frequency after dropping the water onto the immobilized fine particle 90 becomes large; and the detection accuracy of the fine particle 90 increases.

In the case of only water not including the fine particle 90, the shift amount of the resonant frequency is larger than the shift amount when the fine particle 90 exists. For example, a single wavelength of the laser light 60 can be set within a range including the peak vicinity of the initial spectrum and the peak vicinity of the fine particle spectrum after dropping the water.

FIG. 4 is a schematic plan view illustrating a modification of the surface metal film.

In the modification of FIG. 4, the planar configuration of the opening 80a is a cross shape. In the case where the fine particle 90 is placed directly on the surface metal film 80, the chip of the semiconductor laser device 5 should be replaced after the measurement. If the fine particle 90 is placed on a plate that is transparent to the terahertz wave, it is unnecessary to replace the chip.

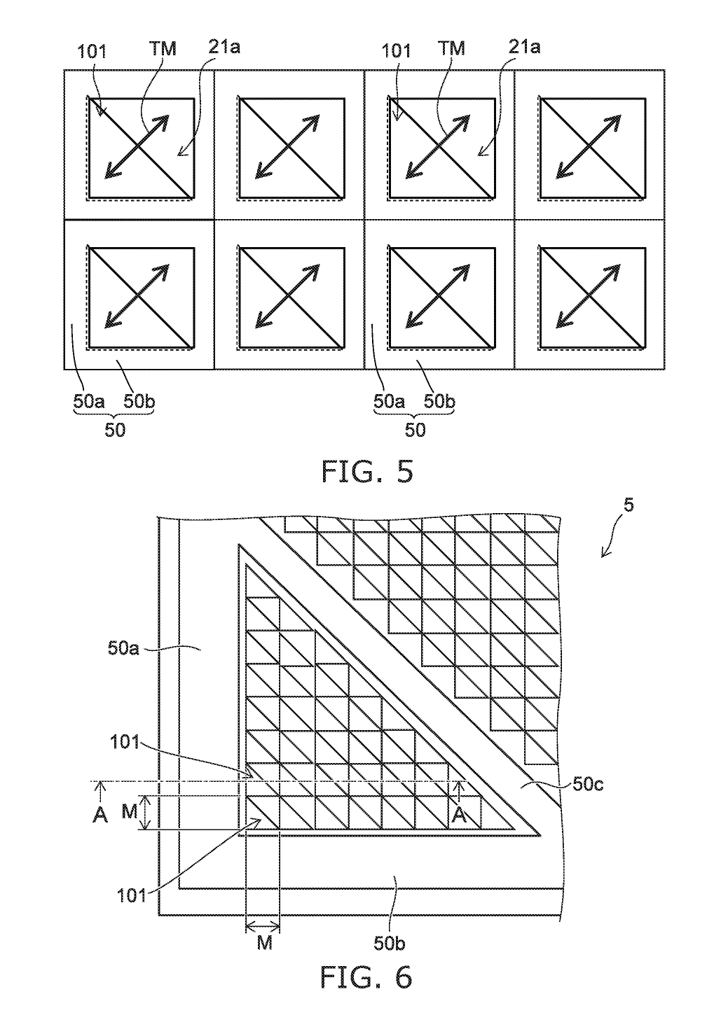

FIG. 5 is a schematic plan view illustrating another example of the arrangement of the openings of the surface metal film.

The pitch of the openings may be equal to the pitch M of the two-dimensional diffraction grating. Or, it is unnecessary for the pitch of the openings to be an integer multiple of the pitch M of the two-dimensional diffraction grating. In other words, it is sufficient for the openings 80a to be arranged so that the resonant frequency is shifted.

FIG. 6 is a schematic plan view of the surface emitting portion of the semiconductor laser device of the first embodiment.

The pit 101 has a configuration in which a triangular pyramid, a truncated triangular pyramid, or the like is cut out downward from the first surface 21a of the stacked body 21. The configuration of the pit 101 is not limited thereto. In the drawing, the opening end of the pit 101 is illustrated by a right triangle. The two sides that sandwich the right angle are parallel respectively to the two sides of frame portions 50a and 50b; and the oblique side is parallel to a stripe portion 50c of the first electrode 50.

The active layer 25 has a configuration in which a relaxation region is stacked alternately with an intersubband transition light emitting region made of a quantum well layer including a well layer and a barrier layer. The quantum well includes, for example, a well layer made of In_{0.669}Ga_{0.331}As doped with Si, and a barrier layer made of In_{0.362}Al_{0.638}As doped with Si. It is more favorable for the quantum well layer to have a multi-quantum well (MQW: Multi-Quantum Well) structure in which at least two well layers and multiple barrier layers are further stacked alternately. Also, the relaxation region also can include a quantum well layer.

A QCL has TM (Transverse Magnetic) polarized light of which the polarization direction is parallel to the front surface of the active layer 25; and for resonator mirrors sandwiching the active layer from the front surface and the back surface as in a p-n junction surface emitting laser, stimulated emission does not occur because the propagation directions of the light and the polarized light are aligned. In other words, it was impossible to realize a VCSEL (Veryical Cavity Surface Emitting Laser: surface emitting laser).

Conversely, in the QCL according to the first embodiment, it is possible to resonate and amplify the stimulated emission light because the propagation direction of the stimulated emission light is a direction parallel to the front surface of the active layer 25. Further, in the case of a structure that is periodic and has anisotropy in the periodic structure, it is possible to extract the stimulated emission light in a direction substantially perpendicular to the front surface of the active layer 25. That is, a surface emitting laser is realizable in which the wavelength region is longer than the mid-infrared region which was previously realizable only by a QCL.

In the surface emitting laser, it is unnecessary to form a resonator by cleaving as in an edge emitting laser; and the decrease of the yield due to the cleaving can be prevented. Further, in an edge emitting laser, the resonator is first formed by the cleaving; therefore, it is necessary to perform inspections after cleaving; and the cost of inspection is high compared to an LED or the like for which the inspections can be performed using an auto-prober or the like for the wafer as-is.

Conversely, the QCL according to the first embodiment can be evaluated by an auto-prober in the wafer state; a large effect of reducing the inspection cost and/or the cost from the perspective of yield can be expected; and mass production and price reduction are easy for QCLs which had previously been expensive.

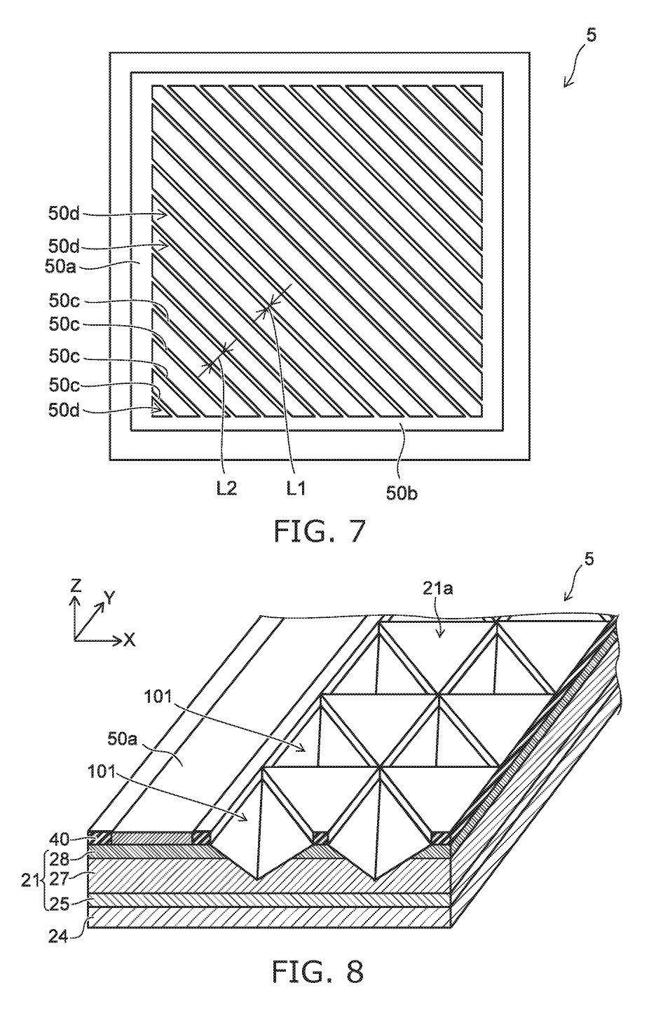

FIG. 7 is a schematic plan view of the first electrode of the surface emitting portion.

For the stripe portion 50c, the width is taken as L1; and the pitch in a direction orthogonal to the stripe portion 50c is taken as L2. The multiple pits 101 are disposed in the region sandwiched between the stripe portions 50c.

FIG. 8 is a partial schematic perspective view of the pit portion.

The stacked body 21 can further include a contact layer 28 on the first layer 27. Also, an insulator layer 40 of SiO₂, etc., can be provided on the first surface 21a. The surface metal film 80 can be planarized by further providing an insulator layer of SiO₂, etc., inside the pits.

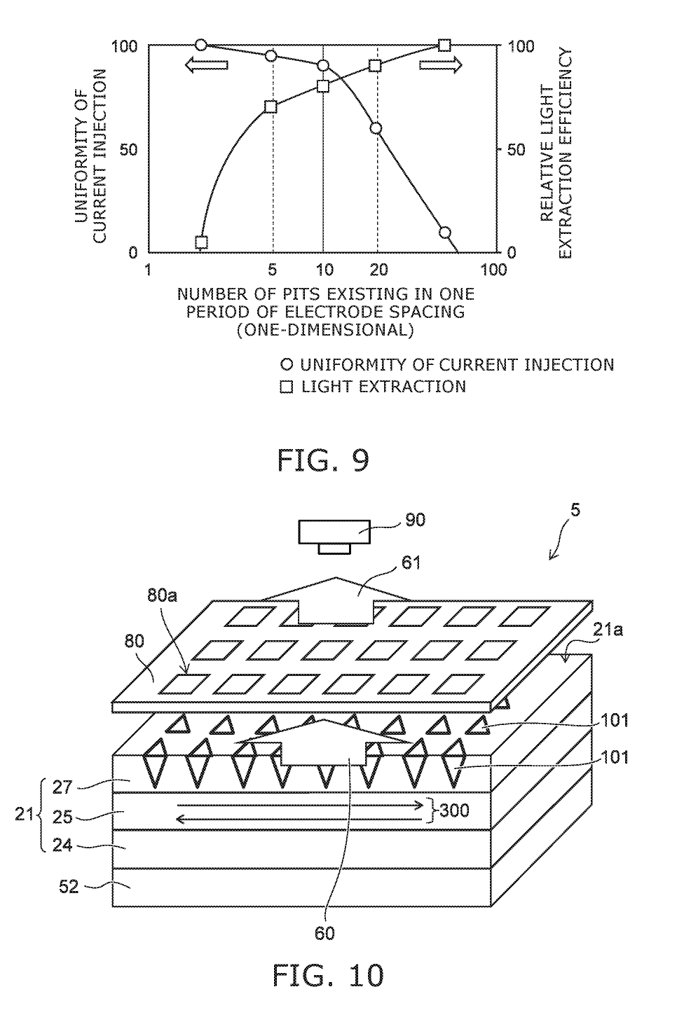

FIG. 9 is a graph illustrating the current injection uniformity dependence and the relative light extraction efficiency dependence with respect to the number of pits.

The horizontal axis is the number of pits inside one period of the stripe portion 50c of the electrode; and the vertical axis is the uniformity of the current injection and the relative light extraction efficiency. In the case where the stripe portion 50c of the first electrode 50 has a one-dimensional periodic structure, the uniformity of the current injection is normalized to be 100 in the case where two pits are included inside one period along a direction orthogonal to the stripe portion 50c.

Also, in the case where the stripe portion 50c of the first electrode 50 has a one-dimensional periodic structure, the relative light extraction efficiency is normalized to be 100 in the case where fifty pits are included inside one period along the direction orthogonal to the stripe portion 50c.

As the number of the pits 101 inside one period along the direction orthogonal to the stripe portion 50c increases, the uniformity of the current injection decreases; but the relative light extraction efficiency increases. In other words, by setting the number of the pits 101 inside one period to be not less than 5 and not more than 20, both the uniformity of the current injection and the laser light extraction efficiency can be realized. Thus, the optimal solution is determined from the relationship between the surface area of an opening 50d of the first electrode 50 and the efficiency of the current injection and the relationship of the effect of the periodic structure of the first electrode 50 on the diffraction effect of the light extraction.

FIG. 10 is a schematic perspective view of a semiconductor laser device according to a second embodiment.

The first electrode is not provided in the semiconductor laser device according to the second embodiment. In other words, the surface metal film 80 functions as the first electrode and supplies a voltage to the surface emitting portion. The first electrode is unnecessary in the second embodiment; therefore, the manufacturing processes can be simple; and a cost reduction is easy. The low cost is favorable in the case where the chip of the semiconductor laser device 5 is replaced. The surface metal film 80 and the surface of the surface emitting portion (the surface of the first layer 27) actually are closely adhered despite being illustrated as being separated in FIG. 10.

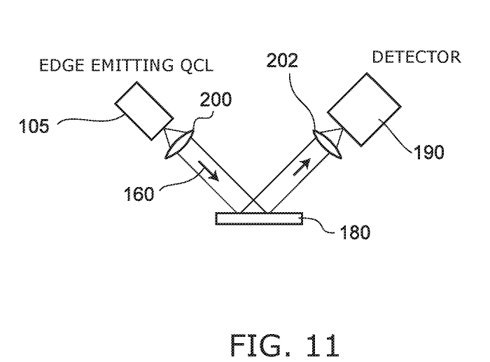

FIG. 11 is a configuration diagram of a laser device according to a comparative example.

A semiconductor laser element 105 that is used as a light source is an edge emitting QCL emitting single-mode laser light. The edge emitting QCL emits the laser light from the ridge waveguide in a direction orthogonal to the end surface of the ridge waveguide. In such a case, the beam diverges; and the cross section of the beam has an elliptical configuration. Therefore, the diverging emitted light is caused to be parallel light by using a collimating lens 200, etc.

The parallel light that is irradiated from the light source 105 is reflected by a reflection plate 180, subsequently is concentrated by a lens 202, and is incident on a detector 190 such as a bolometer, etc.; and the light intensity of the parallel light is detected. The reflection plate 180 can be a metal plate having openings. For a terahertz wave, such an optical configuration is large such that the planar configuration of the laser device is several tens of cm×several tens of cm or the like; and the adjustment of such an optical configuration is not easy.

Conversely, according to the semiconductor laser device of the embodiment, the terahertz wave is emitted from the surface emitting portion substantially perpendicular upward from the active layer 25. Therefore, a complex configuration and a large optical system are unnecessary; therefore, a small semiconductor laser device that can emit a plane terahertz wave with high efficiency is possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1: A semiconductor laser device, comprising:
an active layer configured to emit laser light of a terahertz wave by an intersubband transition, a plurality of quantum well layers being stacked in the active layer;
a first layer having a first surface and being provided on the active layer, a plurality of pits being provided in the first surface to form a two-dimensional lattice; and
a surface metal film provided on the first layer, a plurality of openings being provided in the surface metal film,
each of the pits being asymmetric with respect to a line parallel to a side of the lattice, and
the laser light passing through the plurality of openings and being emitted in a direction substantially perpendicular to the active layer.

2: The semiconductor laser device according to claim 1, wherein the lattice of the first layer includes the pits having configurations of prescribed regions of the first layer cut out from the first surface toward a depth direction.

3: The semiconductor laser device according to claim 1, wherein the openings form a two-dimensional lattice.

4: The semiconductor laser device according to claim 2, wherein the openings form a two-dimensional lattice.

5: The semiconductor laser device according to claim 3, wherein a pitch of the lattice of the openings is different from a pitch of the lattice of the first layer.

6: The semiconductor laser device according to claim 4, wherein a pitch of the lattice of the openings is different from a pitch of the lattice of the first layer.

7: The semiconductor laser device according to claim 1, further comprising a first electrode provided between the first layer and the surface metal film, electrically connected to a surface of the first layer, but insulated from the surface metal film.

8: The semiconductor laser device according to claim 7, wherein
the first electrode includes a frame portion and a plurality of stripe portions, two end portions of each stripe portion being linked to the frame portion, and
the plurality of stripe portions obliquely crosses the frame portion and is arranged to be mutually parallel at a prescribed pitch.

9: The semiconductor laser device according to claim 8, wherein an opening of the first electrode is asymmetric with respect to a line parallel to a side of the lattice of the first layer.

10: The semiconductor laser device according to claim 2, further comprising a first electrode provided between the first layer and the surface metal film, electrically connected to a surface of the first layer, but insulated from the surface metal film.

11: The semiconductor laser device according to claim 3, further comprising a first electrode provided between the first layer and the surface metal film, electrically connected to a surface of the first layer, but insulated from the surface metal film.

12: The semiconductor laser device according to claim 4, further comprising a first electrode provided between the first layer and the surface metal film, electrically connected to a surface of the first layer, but insulated from the surface metal film.

13: The semiconductor laser device according to claim 5, further comprising a first electrode provided between the first layer and the surface metal film, electrically connected to a surface of the first layer, but insulated from the surface metal film.

14: The semiconductor laser device according to claim 6, further comprising a first electrode provided between the first layer and the surface metal film, electrically connected to a surface of the first layer, but insulated from the surface metal film.
